(19) United States
(12) Patent Application Publication
(10) Pub. No.: US 2023/0378395 A1
(43) Pub. Date: Nov. 23, 2023

(54) OPTOELECTRONIC DEVICE WITH A CONTACT LAYER AND A ROUGHENED LAYER ARRANGED THEREON, AND PRODUCTION METHOD

(71) Applicant: ams-OSRAM International GmbH, Regensburg (DE)

(72) Inventor: Wolfgang SCHMID, Gundelshausen (DE)

(73) Assignee: ams-OSRAM International GmbH, Regensburg (DE)

(21) Appl. No.: 18/247,936

(22) PCT Filed: Oct. 8, 2021
(86) PCT No.: PCT/EP2021/077959

§ 371 Date: Apr. 5, 2023

(30) Foreign Application Priority Data
Oct. 8, 2020 (DE) 10 2020 126 442.9

(51) Int. Cl. H01L 33/22; H01L 33/10; H01L 33/30; H01L 33/44; H01L 33/00

(52) U.S. Cl. CPC H01L 33/22; H01L 33/10; H01L 33/30; H01L 33/44; H01L 33/0062

(57) ABSTRACT

The invention relates to an optoelectronic device including a first current spreading layer made of a semiconductor material of a first conductivity type, an active layer which is arranged on the first current spreading layer for generating light, a second current spreading layer which is arranged on the active layer and is made of a semiconductor material of a second conductivity type, a contact layer which is arranged on the second current spreading layer, a roughened layer which is arranged on the contact layer and comprises a roughened surface for coupling out light generated in the active layer, and a metal layer which is arranged on the contact layer.

### CROSS-REFERENCE TO RELATED APPLICATIONS

The present application is a national stage entry from International Application No. PCT/EP2021/077959, filed on Oct. 8, 2021, published as International Publication No. WO 2022/074246 A1 on Apr. 14, 2022, and claims priority to German Patent Application No. 10 2020 126 442.9 filed Oct. 8, 2020, the disclosure content of all of which are hereby incorporated by reference in their entireties into the present application.

### FIELD OF THE INVENTION

The present invention relates to an optoelectronic device having a contact layer and a roughening layer arranged above the contact layer. Furthermore, the invention relates to a method of manufacturing such an optoelectronic device.

### BACKGROUND OF THE INVENTION

Roughening is important for efficient coupling of light from optoelectronic devices, in particular thin-film LEDs (light emitting diodes) or infrared LEDs (IREDs or IR LEDs for short). If the roughening is done over several layers of different composition, the roughening may deviate from its optimal structure. Therefore, such composite layer stacks are disadvantageous.

The present invention is based, among other things, on the object of creating an optoelectronic device that can be manufactured inexpensively. In addition, a method for manufacturing the optoelectronic device is to be disclosed.

One object of the invention is solved by an optoelectronic device having the features of claim 1. A further object of the invention is solved by a method for manufacturing an optoelectronic device having the features of independent claim 9. Preferred embodiments and further embodiments of the invention are given in the dependent claims.

### SUMMARY OF THE INVENTION

An optoelectronic device according to an aspect of the present application comprises a first current spreading layer, an active layer, a second current spreading layer, a contact layer, and a roughening layer. The aforementioned layers are arranged one on top of the other in the order indicated. However, this does not necessarily mean that the individual layers are arranged directly one above the other. Further layers may be provided which are arranged between the aforementioned layers. Furthermore, the optoelectronic device may comprise further layers arranged below or above the aforementioned stack of layers.

The first current spreading layer, the active layer and the second current spreading layer may form a pn semiconductor diode. The first current spreading layer is made of a semiconductor material of a first conductivity type, while the second current spreading layer is made of a semiconductor material of a second conductivity type. The second conductivity type is opposite to the first conductivity type.

The different conductivity types may have been created by doping, i.e. by introducing impurity atoms into the semiconductor material. For example, the first conductivity type can be a p-type conductivity and the second conductivity type can be an n-type conductivity. Opposite dopants are also conceivable.

The active layer, which can also be referred to as an optically active layer, can be made of a semiconductor material and is configured to generate light. Charge carriers or electron/hole pairs can recombine in the active layer. The energy released during recombination is at least partially emitted as light, i.e. as a photon.

Current flows to and from the active layer through the first and second current spreading layers, respectively.

The contact layer arranged on the second current spreading layer and the roughening layer arranged on the contact layer may be made of a semiconductor material, in particular a semiconductor material of the second conductivity type.

The roughening layer has a roughened surface from which the light generated in the active layer is coupled out. The roughening layer can also be referred to as a roughened layer.

Furthermore, a metal layer, which may also be referred to as a metallization layer or top metallization, is arranged on the contact layer. The roughening layer and the metal layer are located on the same side of the contact layer, namely on the side of the contact layer facing away from the second current spreading layer. The roughening layer and the metal layer may be located in different regions of the contact layer, i.e., the roughening layer and the metal layer may be arranged such that they do not overlap each other.

One or more contact elements can be formed from the metal layer, via which the optoelectronic device can be electrically contacted externally. Furthermore, the metal layer can form one or more current paths via which current can be supplied or dissipated.

The second current spreading layer, the contact layer and the roughening layer can be doped to different degrees.

In particular, the current spreading layer, the contact layer and the roughening layer are formed by separate layers arranged on top of each other. The separation into individual layers has the advantage that, for example, InAlP can be used as the material for the current spreading layer, which has a less absorbent effect but does not permit optimum electrical contacting of sufficient quality, whereas, for example, InGaAlP (Al content roughly the same as Ga content or lower) can be used as the material for the contact layer, which permits improved electrical contacting but has a higher absorption. However, this can again be counteracted by keeping the contact layer very thin.

According to at least one embodiment, the current spreading layer may have a higher band gap than the contact layer, or a higher Al content.

The optoelectronic device can be manufactured more cost-effectively than conventional optoelectronic devices, in particular because costly manufacturing steps can be eliminated, as explained below.

Furthermore, the current in the optoelectronic device described here does not flow through the roughening layer but through the second current spreading layer. Therefore, the roughening layer can be less doped, in particular, doping of the roughening layer can be omitted. The lower doping of the roughening layer reduces the light absorption and increases the efficiency of the optoelectronic device.

According to one embodiment, the roughening layer may, for example, have a doping of less than 1*10¹⁸/cm³. According to another embodiment, the doping of the roughening layer may be above said value. According to another embodiment, the doping may be in the range of 5*10¹⁷/cm³ or below.

In addition, the morphology of the epitaxial layers, which are especially the second current spreading layer, the contact layer and the roughening layer, improves and the yields can increase. The morphology depends on the prehistory and deteriorates from layer to layer. Therefore, an improvement of the roughening layer also leads to an improvement of the subsequent layers, especially the second current spreading layer, the active layer and the first current spreading layer.

The roughened surface of the roughening layer may have a roughness of at least 100 nm. In particular, the roughness of the roughening layer may be at least 300 nm or at least 500 nm or at least 600 nm or at least 700 nm or at least 800 nm or at least 900 nm. The surface of the metal layer, in particular the top surface of the metal layer facing away from the contact layer, may have a comparatively low roughness. In particular, the roughness of this surface may be less than 100 nm.

The optoelectronic device may further comprise a carrier. On the carrier, the first current spreading layer, the active layer, the second current spreading layer, the contact layer, and the roughening layer are arranged in the specified order. It should be noted that the first current spreading layer is not necessarily arranged directly on the substrate. It may be provided that one or more further layers are arranged between the carrier and the first current spreading layer. The carrier may, for example, be made of a semiconductor material, an insulator material, for example sintered SiN or AlN, or another suitable material.

For example, at least one mirror layer can be arranged between the carrier and the first current spreading layer. In particular, a metallic and/or a dielectric mirror layer can be provided.

The second current spreading layer, the contact layer and the roughening layer can be an epitaxial layer, i.e. an epitaxially grown layer stack.

The optoelectronic device can be a semiconductor element, in particular a semiconductor chip. Furthermore, the optoelectronic device can be a light-emitting diode (LED), in particular a thin-film light-emitting diode.

The optoelectronic device is configured to emit light. In the present application, the term “light” is understood to include not only light in the visible range, but also electromagnetic radiation in adjacent wavelength ranges, in particular in the ultraviolet and infrared ranges. It may therefore also be envisaged that the optoelectronic device emits ultraviolet (UV) light and/or infrared (IR) light in addition to or as an alternative to visible light. For example, the optoelectronic device may be an infrared LED (IRED or IR LED for short).

At least a part of the optoelectronic device may be made of a semiconductor wafer comprising, for example, InGaAlP or AlGaAs. In particular, the first current spreading layer, the active layer, the second current spreading layer, the contact layer and/or the roughening layer may comprise InGaAlP or AlGaAs. The wavelength of the light emitted by the optoelectronic device is determined in particular by the band gap of the semiconductor material used. InGaAlP, for example, can be used to generate amber light or hyperred light. AlGaAs enables the emission of infrared light, for example.

A method according to another aspect of the present application is for manufacturing an optoelectronic device, for example, an optoelectronic device as described in the present application.

According to the method, there is provided a structure comprising at least the following layers, said layers being stacked in the order indicated:
a first current spreading layer made of a semiconductor material of a first conductivity type,
an active layer for the generation of light,
a second current spreading layer made of a semiconductor material of a second conductivity type,
a contact layer, and
a roughening layer.

The method provides that a surface of the roughening layer is roughened, a contact area of the contact layer is exposed by removing the roughening layer in this area, and a metal layer is deposited on the exposed contact area.

In particular, the contact area of the contact layer is exposed after roughening the roughening layer.

The method described herein may have the embodiments described above in connection with the optoelectronic device.

The surface of the roughening layer can be roughened by means of an etching step. The roughening of the surface is performed in at least one first region of the surface. Simultaneously with the roughening of the surface in the at least one first region, the surface of the roughening layer may be etched above the contact region of the contact layer in at least one second region of the surface. The at least one first region and the at least one second region of the surface of the roughening layer may be different regions and, in particular, may not overlap. Consequently, during the etching step, the surface of the roughening layer is roughened at the locations lying in the at least one first region, while the roughening layer is simultaneously thinned at other locations lying in the at least one second region.

Before roughening the surface of the roughening layer, a first lithographic mask can be created on the roughening layer. For this purpose, a first resist layer, in particular a photoresist layer, is deposited on the roughening layer and structured. The first resist layer can be structured in such a way that no resist layer is located above the contact area of the contact layer, i.e., the first lithographic mask can leave the surface of the roughening layer above the contact area of the contact layer free, so that the roughening layer is etched in this area and thus thinned.

Furthermore, the exposure of the contact area, which can take place after the roughening of the roughening layer, can be effected by a wet etching step.

Before the wet etching step, a second lithographic mask can be applied to the roughening layer, i.e. a second resist layer is deposited on the roughened layer and structured.

Furthermore, it may be provided that a passivation layer is deposited on the structure after the roughening layer has been roughened. In particular, the passivation layer can be deposited before the second lithographic mask is applied. The second lithographic mask can be used to remove a portion of the passivation layer that is adjacent to the contact area after the contact area has been exposed, in particular by means of a further wet etching step.

### BRIEF DESCRIPTION OF THE DRAWING

In the following, embodiments of the invention are explained in more detail with reference to the accompanying drawings. In these schematically show:

FIG. 1 an illustration of an optoelectronic device according to an embodiment; and

FIGS. 2A to 2N representations of a method for manufacturing an optoelectronic device according to an embodiment.

### DETAILED DESCRIPTION

In the following detailed description, reference is made to the accompanying drawings, which form a part of this description and in which specific embodiments in which the invention may be practiced are shown for illustrative purposes. Since components of embodiments may be positioned in a number of different orientations, the directional terminology is for illustrative purposes and is not limiting in any way. It is understood that other embodiments may be used and structural or logical changes may be made without departing from the scope of protection. It is understood that the features of the various embodiments described herein may be combined with each other, unless specifically indicated otherwise. Therefore, the following detailed description is not to be construed in a limiting sense. In the figures, identical or similar elements are provided with identical reference signs where appropriate.

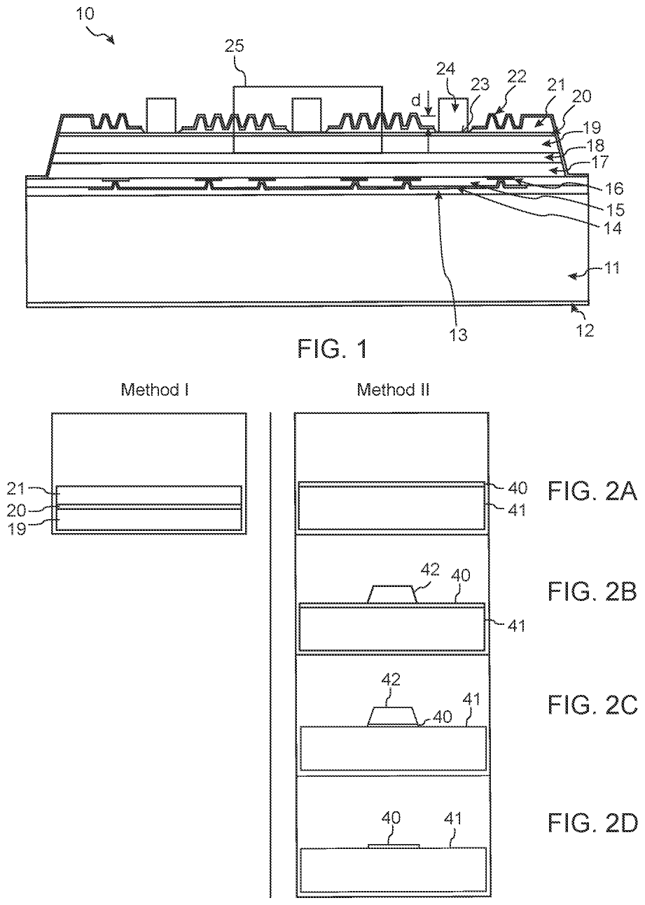

FIG. 1 schematically shows a cross-sectional view of an optoelectronic device designed as a thin-film LED 10 according to an embodiment according to the invention.

The thin-film LED 10 comprises a carrier 11 made of silicon or germanium, for example, on the bottom side of which a backside metallization 12 is arranged. Solder material 13, e.g. AuSn, AulnSn, NiSn or NilnSn, is located on the top side of the carrier 11.

A metal mirror 14, e.g. made of silver or gold, is arranged above the solder material 13, and a dielectric mirror 15, e.g. made of SiN, SiO, NbO or several layers of different materials, is arranged above it.

A contact layer 16 is located on the dielectric mirror 15. The contact layer 16 comprises several contact surfaces with which a p-doped first current spreading layer 17 located above it can be contacted. Furthermore, the contact surfaces of the contact layer 16 are in contact with the metallic mirror 14 through corresponding openings in the dielectric mirror 15. The contact layer 16 may be made of, for example, InGaAlP, AlGaAs, ZnO, ITO (indium tin oxide), or IZO (indium doped zinc oxide). The contact layer 16 can be, for example, p-doped or n-doped, the latter for example when ZnO or ITO is used.

An active layer 18, a second current spreading layer 19, a contact layer 20, and a roughening layer 21 are stacked on top of the first current spreading layer 17 in the order indicated.

The first current spreading layer 17, the active layer 18 and the second current spreading layer 19 form a pn type semiconductor diode. The first current spreading layer 17 is made of a semiconductor material of a first conductivity type, and the second current spreading layer 19 is made of a semiconductor material of a second conductivity type. In the present embodiment, the first conductivity type is a p-type conductivity type and the second conductivity type is an n-type conductivity type.

The first and second current spreading layers 17, 19, the contact layer 20 and the roughening layer 21 can, for example, be made of InGaAlP or AlGaAs, with the first current spreading layer 17 being p-doped and the second current spreading layer 19, the contact layer 20 and possibly also the roughening layer 21 being n-doped. The roughening layer 21 may also be undoped. The active layer 18 can, for example, be made of InGaAlP, InAlGaAsP or quantum wells (QW).

The top surface of the roughening layer 21 is roughened in at least some areas and has a roughness d of at least 100 nm. The roughness d may, for example, indicate the distance between peaks and valleys of the roughening layer 21, as shown in FIG. 1.

A passivation layer 22, for example of SiN or SiO, is deposited on the roughening layer 21.

The roughening layer 21 and the passivation layer 22 are removed in some areas to expose contact areas 23 on the top surface of the contact layer 20. A metal layer 24, for example of AuGe and/or Au, is deposited on the exposed contact areas 23. The top surface of the metal layer 24 may have a roughness of less than 100 nm.

To manufacture the thin-film LED 10 shown in FIG. 1, the first current spreading layer 17 is first defined on the p-doped side on an LED semiconductor wafer, after which the dielectric mirror is deposited and this is opened at the desired locations. Then the metallic mirror 14 is deposited, which is encapsulated if necessary, and the solder material 13 is deposited on top.

The LED semiconductor wafer is then soldered and/or bonded to the carrier wafer 11, and the original substrate of the LED semiconductor wafer is detached.

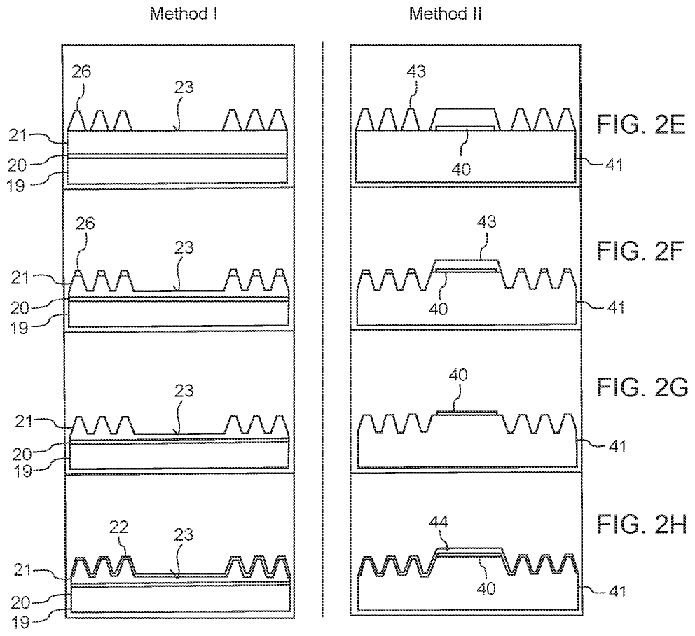

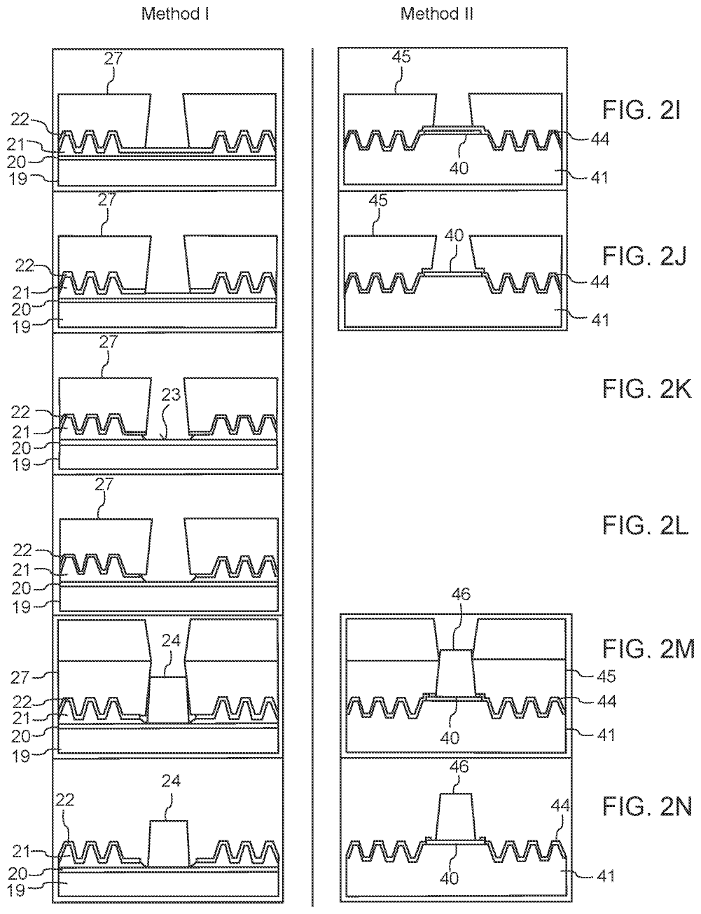

The further steps of the method for manufacturing the thin film LED 10 are schematically shown in FIGS. 2A to 2N. Thereby, on the left side of FIGS. 2A to 2N, a method I for manufacturing the thin-film LED 10 is shown as an embodiment according to an aspect of the present application. The method I is contrasted on the right side of FIGS. 2A to 2N with a method II, not according to the invention, for manufacturing a thin-film LED.

The area of the thin film LED 10 shown in FIGS. 2A to 2N is indicated by a rectangle 25 in FIG. 1.

FIG. 2A shows that in method I, the substrate 11 (not shown) is provided with an epitaxial structure attached thereto comprising the n-doped second current spreading layer 19, the contact layer 20 arranged thereabove, and the roughening layer 21 arranged above the contact layer 20.

In method II, in contrast to method I, a contact layer 40 is the top layer of the epitaxial structure and is deposited on an n-doped layer 41.

In method II, the contact layer 40 is first patterned using a lithography step A.

In FIG. 2B, a resist layer 42 is disposed to the contact layer and is structured in such a way that only the later contact areas are covered by the resist.

In FIG. 2C, the contact layer 40 is removed outside the contact area, and in FIG. 2D, the resist layer 42 is removed.

In method I, the steps shown in FIG. 2B to 2D are not required.

In a subsequent lithography step B, a roughened structure is generated in both methods I and II.

FIG. 2E shows that in method I a resist layer 26 of photoresist is applied to the roughening layer 21 to be roughened and structured. The roughening layer 21 is not protected by the resist layer 26 above the subsequent contact area 23.

In method II, a similar resist layer 43 is applied and structured, although here the already structured contact layer 40 is protected by the resist layer 43.

Subsequently, in both methods I and II, the roughened structure is etched by plasma etching as shown in FIG. 2F. In method II, it must be ensured that the resist layer 43 remains in the later contact area and that the underlying contact layer 40 is not etched. In contrast, in method I the roughening layer 21 is etched in an area above the later contact area 23 and is thereby thinned. The resist removal may therefore be as large as desired.

In FIG. 2G, the remaining resist is removed in both methods I and II.

After roughening and creating a mesa, the semiconductor in FIG. 2F is coated with a passivation layer 22 or 44.

Then, in a lithography step C, the n-contact and the current bar are generated.

To this end, in FIG. 21, a resist layer 27 or 45 is first applied to the passivation layer 22 or 44 and structured in such a way that the passivation layer 22 or 44 is exposed in an area above the subsequent contact area.

In FIG. 2J, the passivation layer 22 or 44 is opened in the area not covered by the resist layer 27 or 45.

Only in method I is the remainder of the roughening layer 21 opened up to the contact layer 20 in a wet etching step shown in FIG. 2K in order to expose the contact area 23. The etching medium is selected so that there is high selectivity, i.e. the roughening layer 21 is etched much faster than the contact layer 20.

Optionally, as shown in FIG. 2L, the protruding passivation 22 can be etched back in a further wet etching step.

In both methods I and II, metal layers 24 and 46, respectively, also called top metallization, are deposited for n-type contact and current distribution in FIG. 2M.

Using a lifting technique, the metals in the unwanted areas are removed in FIG. 2N.

As a variant, in method I, the roughening layer 21 above the contact area 23 may not be etched in the etching step shown in FIG. 2F, but may be etched separately in the lithography step C.

The method I according to one aspect of the application makes it possible to save several process steps compared to the method II not according to the invention. Since in the epitaxial structure shown in FIG. 2A the contact layer 20 is not located on the upper side, the lithography step A including the control of the contact layer, its etching including rinsing as well as the control of the final structure is omitted. This compares with only one or two wet etching processes (cf. FIGS. 2K and 2L), which are, however, considerably less expensive than the processes saved. Therefore, manufacturing costs can be reduced by method I compared to method II.

Furthermore, the re-etching of the passivation layer (cf. FIG. 2L) can optionally be omitted, which results in a further cost advantage.

In addition to the cost aspect, a major advantage of method I is that the photoresist can be completely removed during etching (see FIG. 2F). As in method II, care does not have to be taken that the contact layer is attacked or removed by excessive removal of the photoresist. As a result, the upper structures can become more rounded in method I. According to simulations, this has advantages for the radiation characteristic, which approaches a Lambertian characteristic.

In an LED manufactured according to method II, the current flows through the n-doped layer 41, the surface of which is roughened. Doping of InGaAlP layers with e.g. Te leads to a deterioration of the crystal quality, the extent of which increases with the thickness of the layer. In the LED manufactured according to method I, the current coming from the metal contacts no longer flows through the roughening layer 21, but through the n-doped second current spreading layer 19. Therefore, the roughening layer 21 can be doped to a lesser extent or even not at all, which reduces the light absorption in the roughening layer 21 and increases the efficiency of the LED.

The second current spreading layer 21 has a smaller thickness than the roughening layer 41 in the LED manufactured by method II. This improves the crystal quality of the entire epitaxial structure, which usually means advantages for the yield.

Furthermore, by saving one lithography layer, the necessary tolerances of the remaining layers to each other are also reduced.

For hyperred (Lₚₑₐₖ≈650 nm), a superlattice of InGaAlP is currently used as the current spreading layer, where the Al concentration in the layers varies: high Al content in doped layers and low Al content in an undoped layer. The charge carriers provided in the doped layers are expected to reside predominantly in the undoped layer, where they have high mobility due to the lack of doping, resulting in high conductivity along the layers.

In an LED according to one aspect of the present application, the superlattice may also serve as a contact layer. For example, for the emission of hyperred light, the superlattice can be replaced by an InGaAlP layer with an Al/(Al+Ga) ratio of about 25%. This layer can serve as a contact layer.

For shorter emission wavelengths, the energy approaches the absorption edges in InGaAlP, so high Al grades are advantageous there. For example, for red (Lₚₑₐₖ≈640 nm) or shorter wavelength light, InAlP could therefore be advantageous as a current spreading layer. In this case, a separate contact layer is necessary. Its Al content should be chosen so that Al/(Al+Ga)=70% is not exceeded. Because of the stronger absorption in the layer, it should be thin, e.g. 100 nm.

Similarly, for the roughening layer for red or shorter wavelength light, an InAlP will be ideal. In the case of hyperred, an InGaAlP could also be suitable from an optical point of view. From an etching point of view, a high Al content could also be advantageous because greater selectivity is then possible in the wet chemical etching of the roughening layer.

For the emission of infrared light, a layer structure of AlGaAs with different Al contents is usually selected. For the roughening layer, on the other hand, InGaAlP could be advantageous, since it provides a very high etch selectivity to the contact layer. In addition, the layer can simultaneously facilitate the removal of the substrate, e.g. in wet chemical etching.

In the following table 1, parameters of various LEDs are given as examples of embodiments. In detail, exemplary material compositions for the roughening layer, the contact layer, the n-doped second current spreading layer and the passivation layer as well as chemicals for wet chemical etching of the roughening layer are given for LEDs emitting amber, hyperred and infrared, respectively.

TABLE 1

| | InGaAlP LED for | InGaAlP LED for | |
|---|---|---|---|
| Material | Amber | Hyperred | AlGaAs-IRED |
| roughening | In_{0.5}Al_{0.5}P | In_{0.5}Al_{0.5}P | InGaAlP, InGaP, |
| layer, approx. | | | AlGaAs |
| 1 μm | | | |
| contact layer, | In_{0.5}Ga_{0.25}Al_{0.25}P | In_{0.5}Ga_{0.35}Al_{0.15}P, at | Al_{0.1}Ga_{0.9}As |
| approx. 100 nm | | the same time current | |
| | | spreading layer | |
| n-doped second | In_{0.5}Al_{0.5}P | In_{0.5}Ga_{0.35}Al_{0.15}P | Al_{0.2}Ga_{0.8}As |
| current spreading | | | |
| layer, approx. | | | |
| 1-3 μm | | | |
| Chemical for wet | HCl strongly | HCl strongly | For InGaAlP as a |
| chemical etching | diluted with H₂O | diluted with H₂O | roughening layer: |
| of the roughening | | | HCl, possibly |
| layer | | | diluted with H₂O; |
| | | | For AlGaAs with a |
| | | | high Al content as |
| | | | a roughening layer: |
| | | | HF |
| Passivation | SiN approx. 80 nm | SiN approx. 90 nm | SiN approx. 120 nm |
| layer | | | |

1. An optoelectronic device, comprising:
a first current spreading layer made of a semiconductor material of a first conductivity type,
an active layer arranged on the first current spreading layer for generating light,
a second current spreading layer of a semiconductor material of a second conductivity type arranged on the active layer,
a contact layer arranged on the second current spreading layer,
a roughening layer arranged on the contact layer and having a roughened surface for coupling out light generated in the active layer, and
a metal layer arranged on the contact layer,
wherein the optoelectronic device is a thin film light emitting diode.

2. The optoelectronic device according to claim 1, wherein the roughening layer has a roughness of at least 100 nm and a surface of the metal layer has a roughness of less than 100 nm.

3. The optoelectronic device according to claim 1, further comprising a carrier on which the first current spreading layer is arranged.

4. The optoelectronic device according to claim 3, wherein at least one mirror layer is arranged between the carrier and the first current spreading layer.

5. The optoelectronic device according to claim 1, wherein the first conductivity type is a p-type conductivity type and the second conductivity type is an n-type conductivity type.

6. The optoelectronic device according to claim 1, wherein the second current spreading layer, the contact layer and the roughening layer are an epitaxially grown layer stack.

7. (canceled)

8. The optoelectronic device according to claim 1, wherein the first current spreading layer, the active layer, the second current spreading layer, the contact layer and/or the roughening layer comprise InGaAlP or AlGaAs.

9. A method for manufacturing an optoelectronic device, wherein
a structure is provided comprising a first current spreading layer made of a semiconductor material of a first conductivity type, an active layer for generating light arranged on said first current spreading layer, a second current spreading layer made of a semiconductor material of a second conductivity type arranged on said active layer, a contact layer arranged on said second current spreading layer, and a roughening layer arranged on said contact layer,
a surface of the roughening layer is roughened,
a contact area of the contact layer is exposed, and
a metal layer is deposited on the exposed contact area,
wherein a first resist layer is deposited and structured on the roughening layer before roughening the surface of the roughening layer, and
wherein the first resist layer is structured such that no resist layer is located above the contact area of the contact layer.

10. The method according to claim 9, wherein to roughen the surface of the roughening layer, the roughening layer is etched in at least a first region and simultaneously the roughening layer is etched in at least a second region above the contact region of the contact layer.

11-12. (canceled)

13. The method according to claim 9, wherein the exposure of the contact area is performed by a wet etching step.

14. The method according to claim 13, wherein a second resist layer is deposited and structured above the roughening layer before the wet etching step.

15. The method according to claim 9, wherein a passivation layer is deposited on the structure after roughening the surface of the roughening layer, and a portion of the passivation layer adjacent to the contact region is removed after exposing the contact region.
